(19) United States
(12) Patent Application Publication
(10) Pub. No.: US 2004/0227509 A1
(43) Pub. Date: Nov. 18, 2004

(54) POSITION DETECTOR FOR A MOVING PART IN A PIPE

(75) Inventor: Aydin Ucan, Ludwigsburg (DE)

Correspondence Address: FACTOR & LAKE, LTD, 1327 W. WASHINGTON BLVD., SUITE 5G/H, CHICAGO, IL, 60607, US

(73) Assignee: EISENMANN LACKTECHNIK KG, Boblingen (US)

(21) Appl. No.: 10/708,359

(22) Filed: Feb. 26, 2004

(30) Foreign Application Priority Data
Feb. 28, 2003 (DE) 103 09 142.4

(51) Int. Cl. G01N 27/72; G01R 33/00

(52) U.S. Cl. 324/220; 324/207.24; 324/261

(57) ABSTRACT

A position detector for the position of a pig movable in a pipeline comprises an annular radially magnetized permanent magnet and a magnetic field sensor arranged on the pipeline.

### SUMMARY OF INVENTION

The invention relates to a position detector for a moving part in a pipe, with a permanent magnet connected to the moving part and a magnetic field sensor arranged on the pipe.

Position detectors of this kind are used to measure the position of pigs in pipelines. The pig is fitted with an internal magnet, the geometrical and magnetic axis of which coincides with the pipe axis. A magnetic field sensor is arranged on the outside of the pipe through which the pig is moved. This can be a magnetic or inductive sensor.

It has now been recognized that such position detectors are unfavourable for several reasons: on the one hand, the magnetic field built up at the location of the magnetic field sensor is small compared with the field prevailing at the ends of the permanent magnet. In addition, two positions are obtained in which the magnetic field sensor responds, to be precise when one of the two faces of the permanent magnet respectively is opposite the magnetic field sensor. For unambiguous position detection, the current output signal of the magnetic field sensor must thus be evaluated together with output signals of the magnetic field sensor obtained in the past. In addition, when the pig and magnetic field sensor are exactly opposed, there is no sharp change in the magnetic field sensor output signal associated with small movements of the moving part.

The permanent magnet and magnetic field sensor must also be arranged close to one another. If there is a large distance between magnet and sensor, very sensitive magnetic field sensors would be required, e.g. coils with a large diameter, which take up too much space for many applications.

A position detector according to the preamble of claim 1 is therefore to be developed by the present invention such that a stronger change in the magnetic field is obtained when the moving part approaches the magnetic field sensor.

This object is achieved according to the invention by a position measuring device with the features indicated in claim 1.

In the position detector according to the invention, the field produced by the permanent magnet runs in a direction that has a radial extension component with reference to the pipe axis. In the relative movement between the moving part and the pipe, the magnetic field of the permanent magnet is thus intersected in a direction inclined towards the magnetic axis, due to which greater changes in the magnetic field result. In the arrangement of the permanent magnet according to the invention, the faces of the magnet can also lie closer to the inner wall of the pipe, resulting in a smaller minimum distance between magnetic field sensor and permanent magnet and thus a higher amplitude of the output signal of the magnetic field sensor.

The measure according to the invention can be realized without any notable additional costs.

Advantageous developments of the invention are indicated in the sub-claims.

The development of the invention according to claim 2 is advantageous in respect of particularly high strength of the magnetic field and strong changes in the magnetic field when the moving part approaches the exact opposite position in relation to the magnetic field sensor.

claim 3 is advantageous insofar as the unit formed by the moving part and the permanent magnet is rotationally symmetrical. Such a unit can also be realized without any significant mechanical weakening of the moving part.

An arrangement such as indicated in claim 4 is advantageous insofar as a wide selection of inexpensive bar-shaped permanent magnets is obtainable on the market. They can also be inserted easily into a hole in the moving part, little effort likewise being required to produce the hole.

Due to the pole shoe running in a circumferential direction provided according to claim 4, it is nevertheless guaranteed that the output signal of the magnetic field sensor is largely independent of the angular position of the moving part (and thus of the permanent magnet) with reference to the pipe axis.

With the development of the invention according to claim 5, it is achieved that the magnetic field generated by the permanent magnet is closed via a small gap between the ends of the pole shoe. There are thus relatively high field strengths there, as the stray field is small.

The magnetic field sensor is exposed to this high field between the ends of the pole shoe according to claim 6. This sensitive arrangement makes it possible to manage on the whole with relatively weak permanent magnets. Weak permanent magnets are advantageous in the respect that components that should not be exposed to any stronger magnetic fields are possibly arranged in other pipe sections that the moving part likewise passes. Even if media that contain magnetizable or magnetic particles are conveyed in the pipe, it is advantageous if no stronger magnetic field is emitted by the moving part.

With the development of the invention according to claim 7, yet a further increase in the sensitivity of the position detector is obtained, as the magnetic field currents between both gaps in the pole shoe arrangement are used for measuring.

A moving part such as indicated in claim 8 is well suited to the separation current-wise of sections of the pipe.

The development of the invention according to claim 9 is also advantageous because a seal is obtained between the moving part and the internal wall of the pipe with little friction between moving part and internal pipe wall. Since the permanent magnet according to claim 9 is arranged in the connecting section of the moving part having a reduced diameter, its presence does not adversely affect the sealing properties of the head sections cooperating with the internal wall of the pipe.

### BRIEF DESCRIPTION OF DRAWINGS

The invention is explained below in greater detail on the basis of practical examples with reference to the drawing.

FIG. 1 shows a diagrammatic section through a pipe with a pig movable therein and a position detector for the position of the pig;

FIG. 2 shows an axial section through the pig shown in FIG. 1;

FIG. 3 shows an enlarged view in perspective of an annular permanent magnet, which is embedded in the pig according to FIGS. 1 and 2; and

FIG. 4 shows a transverse section through a pipe, a pig movable in this and a modified position detector for the pig position.

### DETAILED DESCRIPTION

In the drawing, a pipeline represented by 10 forms part of a pipeline system, via which paint is supplied to a spraying system not shown in the drawing, e.g. for spray-painting vehicle bodies.

A pig designated 12 overall is shown in the pipeline 10. The pig has an essentially bone-shaped form with two head sections 14, 16, which cooperate closely with the inner surface of the pipe, and a connecting section 18 of reduced diameter lying between the head sections 14, 16.

The pig 12 is symmetrical on the whole to a central plane.

Incorporated into the connecting section 18 is a central groove 20 running in a circumferential direction, in which groove an annular permanent magnet 22 sits flush. The permanent magnet 22 represents with its circumferential surface a smooth continuation of the circumferential surface of the connecting section 18. In practice the permanent magnet 22 can be glued into the groove 20. If the pig 12 is made of synthetic material, the permanent magnet 22 can be moulded into the connecting section 18 by injection moulding or casting.

It goes without saying that the permanent magnet 22 can also be composed of a number of sector-shaped segments.

A magnetic field sensor 24 sits on the outside of the pipeline 10. This can be a magnetic or inductive magnetic field sensor. The magnetic field sensor 24 is connected via an operating line 26 and a signal line 28 to an operating/evaluation circuit not represented in the drawing.

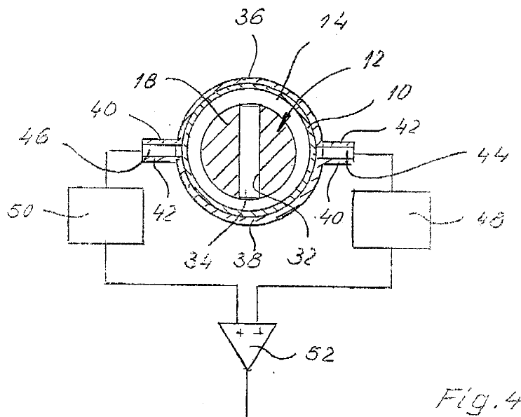

As can be seen from FIG. 3, the annular permanent magnet 22 is magnetized in a radial direction. The direction of magnetization is indicated by arrows 30.

It is recognized that when the pig 12 approaches the magnetic field sensor 24, only a single signal pulse is obtained, which is to be attributed to the radial field of the permanent magnet 22. It is also recognized that the distance between the outer surface of the permanent magnet 22 and the magnetic field sensor 24 is only small when they are in an opposing position, so that the magnetic field sensor 24 is acted upon by high field strength.

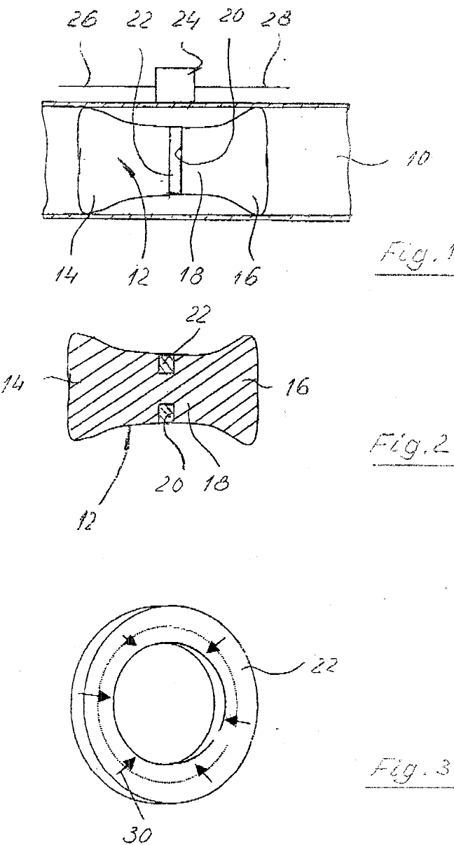

In the practical example according to FIG. 4, components that have already been described above with reference to FIGS. 1 to 3 are again provided with the same reference symbols. These components do not need to be described in detail again below.

In the connecting section 18 of the pig 12, a transverse hole 32 is now provided. Fixedly arranged, e.g. glued in this is an axially magnetized bar-shaped permanent magnet 34. The magnetization of the permanent magnet 34 thus extends likewise in a radial direction in relation to the pipe axis.

Placed onto the outside of the pipeline 10 are two respectively basically semi-circular pole shoes 36, 38. These have a circumferential extension in each case of less than 180°, here roughly 160°, and flat flanges 40, 42 are formed on the ends respectively of the pole shoes 36, 38. These each extend basically parallel to a diameter line.

The pole shoes 36 and 38 are made of a material of high magnetic permeability and are screwed firmly, glued firmly or otherwise fastened on the outer surface of the pipeline 10.

Lying between the flanges 40 and 42 of the pole shoes 36, 38 are flat spaces, via which the feedback of the external field of the permanent magnet 34 is effected when this is opposite the pole shoes 36, 38. The strength of the field prevailing between the flanges 40, 42 of the pole shoes 36, 38 is evidently very largely independent of the angular position of the bar-shaped permanent magnet 34.

Arranged in the gaps between the flanges 40, 42 are two Hall probes 44, 46. These are connected respectively via a cable to a related operating/evaluation circuit 48 and 50, which supply an injected measuring current to the Hall probes and measure the Hall voltages returned by the Hall probes.

At the outputs of the operating/evaluation circuits 48, 50, signals are obtained that indicate the direction and amount of the magnetic field.

The output signals of the two operating/evaluation circuits 48, 50 are combined by an adder 52, the output signal of which thus permits detection with a high level of sensitivity of whether the permanent magnet 34 is between the pole shoes 36, 38 or not. The position of the pig 12 can be measured with corresponding accuracy.

1. Position detector for a moving part in a pipe with a permanent magnet connected to the moving part and a magnetic field sensor arranged on or near the pipe, characterized in that the magnetization of the permanent magnet runs in a direction that has a radial extension component with reference to the axis of the pipe.

2. Position detector according to claim 1, characterized in that the direction of magnetization runs in a radial direction with reference to the pipe axis.

3. Position detector according to claim 1, characterized in that the permanent magnet is annular and the ring axis and pipe axis coincide.

4. Position detector according to claim 1, characterized in that the permanent magnet is bar-shaped and at least one pole shoe running in a circumferential direction is provided on the pipe in the vicinity of the magnetic field sensor.

5. Position detector according to claim 4, characterized in that two pole shoes are provided, which extend in each case over somewhat less than 180° in a circumferential direction and are arranged such that the pole shoe ends are spaced in a circumferential direction, preferably equally spaced.

6. Position detector according to claim 5, characterized in that the magnetic field sensor is arranged near or in the pole gap lying between two pole shoe ends.

7. Position detector according to claim 6, characterized in that two magnetic field sensors are provided and one of the magnetic field sensors is arranged in each of the two pole shoe gaps and that the output signals of the two magnetic field sensors are combined by an adder.

8. Position detector according to claim 1, characterized in that the moving part is rotationally symmetrical.

9. Position detector according to claim 8, characterized in that the moving part has two head sections cooperating closely with the internal wall of the pipe and a connecting section of reduced diameter lying in between and that the permanent magnet is arranged in the connecting section.
